(19) United States
(12) Patent Application Publication
(10) Pub. No.: US 2025/0194198 A1
(43) Pub. Date: Jun. 12, 2025

(54) SEMICONDUCTOR DEVICE WITH AN ETCH STOP LAYER AT THE MIDDLE OF LINE

(71) Applicant: INTERNATIONAL BUSINESS MACHINES CORPORATION, ARMONK, NY (US)

(72) Inventors: Liqiao Qin, Albany, NY (US); Tao Li, Slingerlands, NY (US); Ruilong Xie, Niskayuna, NY (US); Eric Miller, Albany, NY (US)

(21) Appl. No.: 18/533,085

(22) Filed: Dec. 7, 2023

(51) Int. Cl. H01L 29/66; H01L 21/8234; H01L 23/522; H01L 27/088; H01L 29/06; H01L 29/08; H01L 29/423; H01L 29/775; H01L 29/786

(52) U.S. Cl. CPC H10D 64/017; H01L 23/5226; H10D 30/014; H10D 30/43; H10D 30/6735; H10D 30/6757; H10D 62/121; H10D 62/151; H10D 84/0149; H10D 84/038; H10D 84/83

(57) ABSTRACT

A semiconductor device includes a first transistor adjacent to a second transistor and an etch stop layer within an interlayer dialectic (ILD) to separate a lateral contact and a plurality of backside source/drain region-gate cut dielectric layers. The lateral contact connects a via over a first source/drain region of the first transistor to a second source/drain region of the second transistor.

### BACKGROUND

### Technical Field

The present disclosure generally relates to transistors, and more particularly, to electrical connection formation in transistor structure and methods of creation thereof.

### Description of the Related Art

Contacts provide a way to establish electrical connections within a transistor or to other transistors and enable efficient signal transmission, improved device performance, and enhanced manufacturing processes. In a typical transistor structure, the electrical connection established by the contacts provides a pathway for electrical signals, current, and voltage to flow, allowing communication between different components of an integrated circuit.

### SUMMARY

According to an embodiment, a semiconductor device includes a first transistor adjacent to a second transistor and an etch stop layer within an interlayer dialectic (ILD) to separate a lateral contact, and a plurality of backside source/drain region-gate cut dielectric layers. The lateral contact connects a via over a first source/drain region of the first transistor to a second source/drain region of the second transistor.

In some embodiments, which can be combined with the previous embodiment, the lateral contact is located between the via and the etch stop layer.

In some embodiments, which can be combined with one or more previous embodiments, a contact of the second source/drain region is extended through the etch stop layer.

In some embodiments, which can be combined with one or more previous embodiments, the contact of the second source/drain region is located between two adjacent backside source/drain region-gate cut dielectric layers.

In some embodiments, which can be combined with one or more previous embodiments, the first source/drain region is connected to a backside power rail (BPR) through a direct backside contact (BSCA).

In some embodiments, which can be combined with one or more previous embodiments, the lateral contact is located above the first source/drain region and the second source/drain region.

According to another embodiment, a semiconductor device includes a first transistor adjacent to a second transistor and an etch stop layer within an interlayer dialectic (ILD) to separate a lateral contact, and a plurality of backside source/drain region-gate cut dielectric layers. A contact of the second source/drain region is extended through the etch stop layer.

In some embodiments, which can be combined with the previous embodiment, the lateral contact connects a via over a first source/drain region of the first transistor to a second source/drain region of the second transistor.

In some embodiments, which can be combined with one or more previous embodiments, the lateral contact is located between the via and the etch stop layer.

In some embodiments, which can be combined with one or more previous embodiments, the contact of the second source/drain region is located between two adjacent backside source/drain region-gate cut dielectric layers.

In some embodiments, which can be combined with one or more previous embodiments, the first source/drain region is connected to a backside power rail (BPR) through a direct backside contact (BSCA).

In some embodiments, which can be combined with one or more previous embodiments, the lateral contact is located above the first source/drain region and the second source/drain region.

According to yet another embodiment, a method for forming a semiconductor device includes forming a first transistor, forming a second transistor adjacent to the first transistor, separating a lateral contact and a plurality of backside source/drain region-gate cut dielectric layers through an etch stop layer within an interlayer dialectic (ILD), and connecting a via over a first source/drain region of the first transistor to a second source/drain region of the second transistor through the lateral contact.

In some embodiments, which can be combined with the previous embodiment, the method includes extending a contact of the second source/drain region through the etch stop layer.

In some embodiments, which can be combined with one or more previous embodiments, the contact of the second source/drain region is located between two adjacent backside source/drain region-gate cut dielectric layers, and between the via and the etch stop layer.

In some embodiments, which can be combined with one or more previous embodiments, the method includes connecting the first source/drain region to a backside power rail (BPR) through a direct backside contact (BSCA).

According to yet another embodiment, a method for forming a semiconductor device includes forming a first transistor, forming a second transistor adjacent to the first transistor, and extending a contact of the second source/drain region through the etch stop layer.

In some embodiments, which can be combined with the previous embodiment, the method includes connecting the first source/drain region to a backside power rail (BPR) through a direct backside contact (BSCA).

In some embodiments, which can be combined with the previous embodiment, the contact of the second source/drain region is located between two adjacent backside source/drain region-gate cut dielectric layers, and between the via and the etch stop layer.

According to another embodiment, a semiconductor device includes a first transistor adjacent to a second transistor, an etch stop layer within an interlayer dialectic (ILD), and a contact extending through the etch stop layer to connect a source/drain region to a back end of line (BEOL).

In some embodiments, which can be combined with the previous embodiment, the ILD is configured to separate a lateral contact and a plurality of backside source/drain region-gate cut dielectric layers, and the lateral contact connects a via over a first source/drain region of the first transistor to a second source/drain region of the second transistor.

In some embodiments, which can be combined with one or more previous embodiments, the lateral contact is located between the via and the etch stop layer.

In some embodiments, the lateral contact is located above the first source/drain region and the second source/drain region.

In some embodiments, which can be combined with one or more previous embodiments, a contact of a source/drain region is extended through the etch stop layer.

In some embodiments, which can be combined with one or more previous embodiments, the semiconductor device further includes a source/drain region connected to a backside power rail (BPR) through a direct backside contact (BSCA).

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate a semiconductor device, in accordance with some embodiments.

FIG. 1C illustrates a top view of a semiconductor device, in accordance with some embodiments.

FIGS. 2A-2B illustrate side views of a semiconductor device after the processing of the front end of line (FEOL), in accordance with some embodiments.

FIGS. 3A-3B illustrate side views of a semiconductor device after the formation of the etch stop layer, in accordance with some embodiments.

FIGS. 4A-4B illustrate side views of a semiconductor device after the patterning of the lateral contact, in accordance with some embodiments.

FIGS. 5A-5B illustrate side views of a semiconductor device after the patterning of the middle of line (MOL), in accordance with some embodiments.

FIGS. 6A-6B illustrate side views of a semiconductor device after the deposition of the additional interlayer dielectric (ILD), in accordance with some embodiments.

FIGS. 7A-7B illustrate side views of a semiconductor device after the formation of the back end of line (BEOL), in accordance with some embodiments.

FIGS. 8A-8B illustrate side views of a semiconductor device after the substrate removal, in accordance with some embodiments.

FIGS. 9A-9B illustrate side views of a semiconductor device after removal of the etch stop layer, in accordance with some embodiments.

FIGS. 10A-10B illustrate side views of a semiconductor device after the formation of gate caps, in accordance with some embodiments.

FIGS. 11A-11B illustrate side views of a semiconductor device after patterning the backside source/drain region-gate cut dielectric layers, in accordance with some embodiments.

FIGS. 12A-12B illustrate side views of a semiconductor device after the formation of the backside source/drain region-gate cut dielectric layers, in accordance with some embodiments.

FIGS. 13A-13B illustrate side views of a semiconductor device after the planarization, in accordance with some embodiments.

FIGS. 14A-14B illustrate side views of a semiconductor device after the backside contact (BSCA) patterning, in accordance with some embodiments.

FIGS. 15A-15B illustrate side views of a semiconductor device after the removal of the placeholder, in accordance with some embodiments.

FIGS. 16A-16B illustrate side views of a semiconductor device after the backside contact metallization, in accordance with some embodiments.

FIG. 17 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

According to an embodiment, a semiconductor device includes a first transistor adjacent to a second transistor and an etch stop layer within an interlayer dialectic (ILD) to separate a lateral contact, and a plurality of backside source/drain region-gate cut dielectric layers. The lateral contact connects a via over a first source/drain region of the first transistor to a second source/drain region of the second transistor. Thus, there is enough ILD separation between the lateral contact and the source/drain region.

In some embodiments, which can be combined with the previous embodiment, the lateral contact is located between the via and the etch stop layer. Thus, the lateral contact ensures an electrical connection between the source/drain region and the metal wires.

In some embodiments, which can be combined with one or more previous embodiments, a contact of the second source/drain region is extended through the etch stop layer. Such an extended contact can connect the source/drain region to the metal wires.

In some embodiments, which can be combined with one or more previous embodiments, the contact of the second source/drain region is located between two adjacent backside source/drain region-gate cut dielectric layers. The backside source/drain region-gate cut dielectric layers can isolate the shorting between the contacts.

In some embodiments, which can be combined with one or more previous embodiments, the first source/drain region is connected to a backside power rail (BPR) through a direct backside contact (BSCA). This enables an electrical connection between the source/drain region and the backside power rails.

In some embodiments, which can be combined with one or more previous embodiments, the lateral contact is located above the first source/drain region and the second source/drain region. Thus, the source/drain regions are electrically connected to the metal wires through the lateral contact.

According to another embodiment, a semiconductor device includes a first transistor adjacent to a second transistor and an etch stop layer within an interlayer dialectic (ILD) to separate a lateral contact, and a plurality of backside source/drain region-gate cut dielectric layers. A contact of the second source/drain region is extended through the etch stop layer. Thus, there is enough ILD separation between the lateral contact and the source/drain region.

In some embodiments, which can be combined with the previous embodiment, the lateral contact connects a via over a first source/drain region of the first transistor to a second source/drain region of the second transistor. Thus, the source/drain regions are electrically connected to the metal wires through the lateral contact.

In some embodiments, which can be combined with one or more previous embodiments, the lateral contact is located between the via and the etch stop layer. Thus, the lateral contact ensures an electrical connection between the source/drain region and the metal wires.

In some embodiments, which can be combined with one or more previous embodiments, the contact of the second source/drain region is located between two adjacent backside source/drain region-gate cut dielectric layers. The backside source/drain region-gate cut dielectric layers can isolate the shorting between the contacts.

In some embodiments, which can be combined with one or more previous embodiments, the first source/drain region is connected to a backside power rail (BPR) through a direct backside contact (BSCA). Thus, the first source/drain region is electrically connected to the BPR.

In some embodiments, which can be combined with one or more previous embodiments, the lateral contact is located above the first source/drain region and the second source/drain region. Thus, the source/drain regions are electrically connected to the metal wires through the lateral contact.

According to yet another embodiment, a method for forming a semiconductor device includes forming a first transistor, forming a second transistor adjacent to the first transistor, separating a lateral contact and a plurality of backside source/drain region-gate cut dielectric layers through an etch stop layer within an interlayer dialectic (ILD), and connecting a via over a first source/drain region of the first transistor to a second source/drain region of the second transistor through the lateral contact. Thus, there is enough ILD separation between the lateral contact and the source/drain region.

In some embodiments, which can be combined with the previous embodiment, the method includes extending a contact of the second source/drain region through the etch stop layer. Extending the contact can ensure an electrical connection between the source/drain region and the metal wires.

In some embodiments, which can be combined with one or more previous embodiments, the contact of the second source/drain region is located between two adjacent backside source/drain region-gate cut dielectric layers and between the via and the etch stop layer. The backside source/drain region-gate cut dielectric layers can isolate the shorting between the contacts.

In some embodiments, which can be combined with one or more previous embodiments, the method includes connecting the first source/drain region to a backside power rail (BPR) through a direct backside contact (BSCA). Thus, the first source/drain region is electrically connected to the BPR.

According to yet another embodiment, a method for forming a semiconductor device includes forming a first transistor, forming a second transistor adjacent to the first transistor, and extending a contact of the second source/drain region through the etch stop layer. Thus, there is enough ILD separation between the lateral contact and the source/drain region.

In some embodiments, which can be combined with the previous embodiment, the method includes connecting the first source/drain region to a backside power rail (BPR) through a direct backside contact (BSCA). Thus, the first source/drain region is electrically connected to the BPR.

In some embodiments, which can be combined with the previous embodiment, the contact of the second source/drain region is located between two adjacent backside source/drain region-gate cut dielectric layers, and between the via and the etch stop layer. The backside source/drain region-gate cut dielectric layers can isolate the shorting between the contacts.

According to another embodiment, a semiconductor device includes a first transistor adjacent to a second transistor, an etch stop layer within an interlayer dialectic (ILD), and a contact extending through the etch stop layer to connect a source/drain region to a back end of line (BEOL). Thus, there is enough ILD separation between the lateral contact and the source/drain region.

In some embodiments, which can be combined with the previous embodiment, the ILD is configured to separate a lateral contact and a plurality of backside source/drain region-gate cut dielectric layers, and the lateral contact connects a via over a first source/drain region of the first transistor to a second source/drain region of the second transistor. Thus, the lateral contact ensures an electrical connection between the source/drain region and the metal wires.

In some embodiments, which can be combined with one or more previous embodiments, the lateral contact is located between the via and the etch stop layer. The lateral contact can establish the electrical connection between the source/drain region and the metal wires.

In some embodiments, the lateral contact is located above the first source/drain region and the second source/drain region. Thus, the lateral contact ensures an electrical connection between the source/drain region and the metal wires.

In some embodiments, which can be combined with one or more previous embodiments, a contact of a source/drain region is extended through the etch stop layer. Such an extended contact can connect the source/drain region to the metal wires.

In some embodiments, which can be combined with one or more previous embodiments, the semiconductor device further includes a source/drain region connected to a backside power rail (BPR) through a direct backside contact (BSCA). This enables an electrical connection between the source/drain region and the backside power rails.

The concepts herein relate to electrical connections within the transistors, which are fundamental electronic devices that have revolutionized the field of electronics. Establishing electrical connections within a semiconductor device is a critical aspect of semiconductor manufacturing and comes with several challenges that engineers and manufacturers must address. As semiconductor technology advances, components on a chip become smaller and denser. Establishing electrical connections in tiny spaces becomes increasingly challenging due to the limited available area, and ensuring that each component is connected correctly and reliably is a complex task. Further, misalignment of components or interconnects can result in electrical failures or reduced performance. To that end, electrical connections, also known as interconnects, are used. However, these electrical connections can introduce resistance and capacitance, which can affect signal propagation and speed. Managing these parameters while maintaining low power consumption is challenging. High-density connections can lead to increased power dissipation, which can result in heat buildup and affect device performance. Such requirements can be added to the signal integrity requirements, process variations, failure modes, and scaling to illustrate the vitality of the electrical connections within the semiconductor devices.

To tackle the above-mentioned problems, disclosed is a semiconductor device with an etch stop layer in the middle-of-line (MOL) interlayer dielectric (ILD). In order to enable higher flexibility for the MOL contact to a source/drain region when integrated with the backside power delivery network (BSPDN) process, a lateral contact is disclosed to help leverage the utilization of the first metal layer, M1 wires, that are located above the source/drain region. Moreover, to ensure that there is enough ILD separation between the lateral contact and the source/drain region, an etch stop layer at the MOL ILD is used to improve the MOL contact and backside source/drain region cut process.

Accordingly, the teachings herein provide methods and systems of semiconductor device formation with a lateral contact and an etch stop layer in the MOL ILD. The techniques described herein may be implemented in a number of ways. Example implementations are provided below with reference to the following figures.

### Example Semiconductor Device With MOL Etch Stop Layer Structure

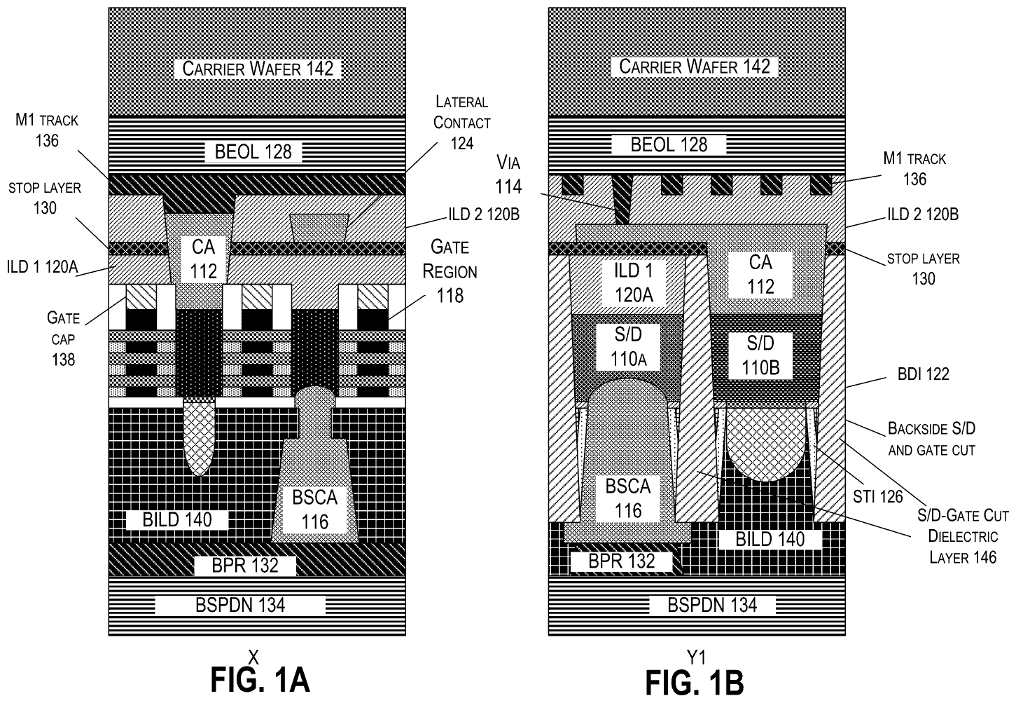

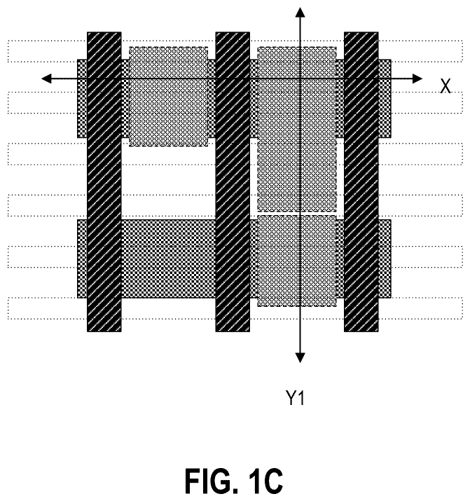

Reference now is made to FIGS. 1A-1B, which are simplified cross-section views of a semiconductor device, consistent with an illustrative embodiment. FIG. 1C depicts a top view of the semiconductor device. For example, FIG. 1A, and other figures denoted by A, illustrate an X section of the semiconductor device and FIG. 1B, and other figures denoted by B, illustrate a Y1 section of the semiconductor device.

The disclosed semiconductor device can include a first source/drain region 110A, a second source/drain region 110A, a contact, CA, 112, a via 114, a backside contact, BSCA, 116, a gate region 118, a first ILD, ILD1, 120A, a second ILD, ILD2, 120B, a bottom dielectric isolation, BDI, 122, a lateral contact 124, a shallow trench isolation, STI, 126, a back end of line, BEOL, 128, an etch stop layer 130, a backside power rail, BPR, 132, a backside power delivery network, BSPDN, 134, a first metal layer, M1 track, 136, a gate cap 138, a bottom ILD, BILD, 140, a carrier wafer 142 and one or more source/drain region-gate cut dielectric layers 144. As a non-limiting example, the first source/drain region 110a can be located on a first transistor, and the second source/drain region 110b can be located on a second transistor.

Generally, the first source/drain region 110A and the second source/drain region 110B are two salient components that play relevant roles in the semiconductor device's operation. In various embodiments, the first source/drain region 110A and the second source/drain region 110B are regions within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The contact 112, located over the second source/drain region 110B, establishes a connection between the second source/drain region 110B and the BEOL 128 via the M1 track 136. The contact 112 ensures efficient electrical routing and connectivity within the semiconductor device. The fabrication of the contact 112 can involve lithography and etching processes to define the contact area. The contact 112 can be made using conductive materials such as a silicide liner, e.g., Ni, Ti, NiPt, an adhesion metal layer, e.g., TiN and conductive metal fill material, e.g., tungsten (W), Co, or Ru. The via 114, which is vertically extended from the M1 track 136 inside the ILD2 120B establishes a connection between the second source/drain region 110B to the M1 track 136.

The BSCA 116 is a region on the backside of the semiconductor device where electrical connections are made. By establishing the electrical contacts, the BSCA 116 ensures the proper functioning of the semiconductor device and facilitates electrical signal transmission.

The BSCA 116 can serve as a thermal interface between the semiconductor device and a heat sink or other cooling mechanisms. By establishing direct contact with the substrate, the BSCA 116 can conduct the heat away from the semiconductor device and contribute to improved thermal dissipation. In some embodiments, the BSCA 116 can help mitigate parasitic effects, such as substrate coupling or substrate noise, from the semiconductor device. In further embodiments, the BSCA 116 can allow for increased integration density in the semiconductor device. In an embodiment, the BSCA 116 connects, i.e., wires, the first source/drain region 110A to the BPR 132.

In various embodiments, the gate region 118 serves as control elements that regulate the flow of current through the semiconductor device. The gate region 118 can comprise a conductive material. The gate region 118 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the channel region. In addition to acting as a switch, modulating the gate voltage can enable the gate region 118 to control the current flowing through the channel region, resulting in amplified output signals.

In an embodiment, the gate region 118 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate region 118, along with other semiconductor device components, can facilitate the miniaturization and integration of electronic circuits. The ability to control the channel region's conductivity through the gate voltage allows for compact and highly efficient circuit designs.

Each of the ILD1 120A and the ILD2 10B can be a layer of insulating material to electrically isolate and provide mechanical support between different layers of conducting and active components. Similarly, the ILD1 120A and the ILD2 120B can enable efficient signal transmission, reduce crosstalk, and ensure the proper functioning of the semiconductor device. In an embodiment, the ILD1 120A and the ILD2 120B can electrically isolate adjacent conducting layers or active components in the semiconductor device. By providing insulation between different layers, the ILD1 120A and ILD2 120B can prevent electrical shorts, reduce (e.g., minimize) leakage current, and ensure that signals are directed only along the desired pathways. In some embodiments, the ILD1 120A and ILD2 120B can help reduce parasitic capacitance between adjacent metal interconnects or active devices and provide mechanical support to the semiconductor device's structure.

The BDI 122 can electrically isolate individual components in the semiconductor device 100, and provide electrical isolation between each of the FETs in the stacked FET. That is, the BDI 122 can ensure that the operation of one component does not interfere with the operation of the others. By using a dielectric layer, which is an insulating layer that does not conduct electricity, the BDI 122 effectively prevents electrical crosstalk between different components and allows each one to operate independently. Further, by electrically isolating each transistor from the other, the BDI 122 can reduce the potential for crosstalk, which is the unwanted transfer of signals between circuit elements, thereby improving the overall performance of the semiconductor device 100. The BDI 122 can isolate the top portion of the BSCA 116 from the gate region 118.

By isolating each transistor, BDI 122 helps to prevent the failure of one transistor from affecting the others. This can improve the overall reliability of the device. Additionally, the BDI 122 allows for more flexibility in device design, as it allows each transistor in the stack to be accessed and controlled independently. This can be beneficial in a variety of applications where specific transistors may need to be activated or deactivated based on certain conditions. In some embodiments, the BDI 122 can help decrease the parasitic capacitance associated with the transistor, which can lead to faster switching times and improved performance.

The lateral contact 124 connects the via 114 over the first source/drain region 110a of the first transistor to the second source/drain region 110b of the second transistor. The lateral contact 124 is located between the via 114 and the etch stop layer 130. Further, the lateral contact 124 is located above the first source/drain region 110A and the second source/drain region 110B.

The lateral contact 124 can create a conducting path or link within the semiconductor device to connect the second source/drain region 110B to the first level metal layer, i.e., the M1 tracks 136, which is shadowed by the first source/drain region 110A. Such a connection can improve routing flexibility.

In various embodiments, the STI 126 helps prevent electrical crosstalk and interference between adjacent components, allowing for the proper functioning of integrated circuits. In various embodiments, the gate region 118, and the gate caps 138, along with the gate spacers (not shown), can define the region where current flows between the first source/drain region 110A and the second source/drain region 110B.

The etch stop layer 130 can form between the ILD1 120A and ILD2 120B. The etch stop layer 130 can be configured to separate the lateral contact 124 and the one or more backside source/drain region-gate cut dielectric layers 144. In some embodiments, the contact 112 of the second source/drain region 110B is extended through the etch stop layer 130.

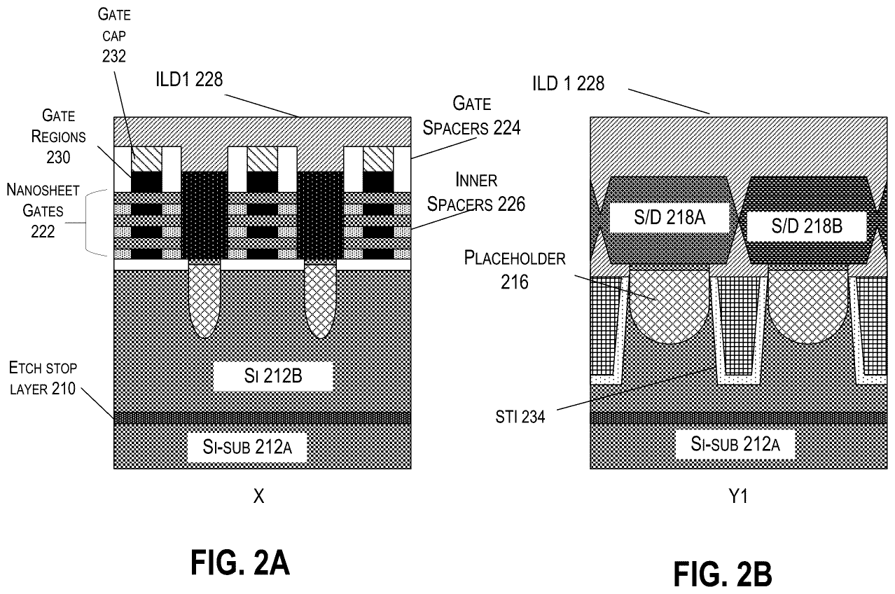

Example Processes for Semiconductor Device With MOL Etch Stop Layer Structures With the foregoing description of an example semiconductor device, it may be helpful to discuss an example process of manufacturing the same. To that end, FIGS. 2-16 illustrate various acts in manufacturing a semiconductor device, consistent with illustrative embodiments. As noted above, figures denoted by A and B illustrate acts of fabrication of the semiconductor device from a different point of view. It is also worth mentioning that the semiconductor device depicted in FIGS. 1A-1B can be the same as the semiconductor device depicted in FIGS. 2-16. For ease of illustration, the fabrication operations depicted therein will be described in the context of forming stacked transistors.

FIGS. 2A-2B illustrate side views of a semiconductor device after the processing of the front end of line (FEOL), in accordance with some embodiments. Once the FEOL processing is performed, the semiconductor can include an etch stop layer 210 between a first substrate, Si-sub, 212A, a second substrate, Si, 212B, placeholders 216, a first source/drain region 218A, a second source/drain region 218b, nanosheets gates 222, gate spacers 224, inner gate spacers 226, an ILD1 228, gate regions 230, gate caps 232, and a STI 234.

In the illustrative example depicted in FIGS. 2A-2B, the semiconductor device is depicted as being on silicon as the first substrate, Si-sub 212A, and the second substrate, Si, 212B, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the Si-sub 210A and the Si 210B may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, an etch stop layer 210 is formed over the Si-sub 212A. The etch stop layer 210 can be a thin layer of material incorporated into the structure of the semiconductor device to provide a selective barrier against etching processes, preventing further removal of underlying materials during fabrication. The etch stop layer 210 can enable precise control over the etching depth and help define the desired device dimensions. The etch stop layer 210 can further provide a stopping point for the etching process, ensuring that specific layers or regions are not etched beyond a certain point, leading to accurate patterning and control of critical features. The etch stop layer 210 can create a distinct separation between different layers or components within the device structure and prevent the undesired etching of underlying layers or materials, enabling the creation of complex, multi-layered structures with well-defined interfaces and boundaries. In some embodiments, the etch stop layer 210 acts as a protective barrier for sensitive or delicate materials to shield such materials from aggressive etchants, preventing damage or degradation during subsequent fabrication acts.

In some embodiments, prior to forming the etch stop layer 210, the Si-sub 212A is prepared by cleaning and removing any impurities or oxide layers. The etch stop layer 210 is deposited onto the Si-sub 212A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 210 can then be selectively etched, stopping at a predetermined depth while protecting the underlying layers. After the etching process, the remaining photoresist can be removed through stripping techniques. While in some embodiments, SiGe is used to form the etch stop layer 210, in some embodiments, silicon nitride (SiN) or silicon oxynitride (SiON) can be used as the etch stop layer 210. In some embodiments, Si 212B is epitaxially grown over the etch stop layer 210.

In some embodiments, a placeholder 216 can be epitaxially grown. The use of the placeholder 216 can provide more flexibility in the fabrication process, allowing for the creation of complex geometries or the integration of different types of materials.

In some embodiments, the nanosheets (e.g., nanosheet gates) 222 can be formed by alternating layers of Si and SiGe (not shown), in which sidewalls of the SiGe layers are indented and covered by the inner gate spacer 226. The SiGe layers can subsequently be removed and replaced with gate region materials.

The gate spacers 224 can be thin insulating layers or materials placed on the sidewalls of the gate regions 230 and the gate caps 232. The gate spacers 224 can help control the effective channel length of the semiconductor device. In various embodiments, the gate regions 230, and the gate caps 232, along with the gate spacers 224, can define the region where current flows between the first source/drain region 218A and the second source/drain region 218B.

In some embodiments, the gate spacers 224 can function as insulating layers between the gate regions 230 and the first source/drain region 218A and the second source/drain region 218B. That is, the gate spacers 224 can help prevent current leakage or short circuits between the gate region 230 and the first source/drain region 218A, and the second source/drain region 218B. Such isolation can help maintain the integrity of the semiconductor device's electrical operation and prevent unintended current flow that could negatively impact the performance of the semiconductor device and reliability.

In further embodiments, the gate spacers 224 can be utilized to modulate the overlapping capacitance between the gate region 230 and the first source/drain region 218A and the second source/drain region 218B. Overlapping capacitance can affect the semiconductor device's electrical characteristics, such as threshold voltage and switching behavior. Thus, by adjusting the thickness and material properties of the gate spacers 224, the overlapping capacitance can be optimized, which can allow for better control and modulation of the semiconductor device's behavior.

In several embodiments, the gate spacers 224 can help mitigate the short-channel effects by physically separating the gate regions 230 from the first source/drain region 218A and the second source/drain region 218B. To that end, the gate spacers 224 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability. In some embodiments, the first source/drain region 218A and the second source/drain region 218B are isolated from the gate caps 232 by the gate spacers 224.

In an embodiment, the gate spacers 224 can serve as barriers that prevent the lateral diffusion of dopant atoms from the first source/drain region 218A and the second source/drain region 218B into the channel region during the doping process. Such diffusion can alter the channel characteristics and compromise the semiconductor device's performance. By confining the dopant diffusion, the gate spacers 224 can contribute to maintaining the desired semiconductor device's characteristics and electrical behavior.

In some embodiments, the gate spacers 224 can be formed over the sidewalls of the gate regions 230. The gate spacers 224 can be formed by deposition techniques. Alternatively, the gate spacers 224 can be formed by etching or selectively epitaxially growing the gate spacers 224 over the sidewalls of the gate regions 230. In some embodiments, the gate spacers 224 can include SiGe.

In an embodiment, the inner gate spacers 226, similar to the gate spacers 224, can function as insulating layers between the gate regions 230 and the first source/drain region 218A and the second source/drain region 218B. In various embodiments, the inner gate spacers 226 can be the same as the gate spacers 224, which are formed over portions of the gate regions 230 confined between the nanosheet gates 222.

The ILD1 228 can be deposited using various techniques such as CVD, spin-on deposition, plasma-enhanced CVD (PECVD), or ALD. In some embodiments, after deposition, planarization techniques are employed to ensure a flat and smooth surface. In an embodiment, chemical mechanical polishing (CMP) can be used to remove excess material and achieve a uniform surface topography. In some embodiments, silicon dioxide (SiO2), or a low-k dielectric, e.g., organosilicates, fluorinated silicates, or porous materials, can be used as ILD1 228. Alternatively, polymer-based materials, such as polyimide or polybenzoxazole (PBO), can be used as ILD1 228.

The gate caps 232 can be formed over a plurality of gate regions. In some embodiments, the gate caps 232 can be made of the same materials as the gate spacers 224 and the inner gate spacers 226.

In some embodiments, the gate region 230 can include a thin layer of gate dielectric and gate metals (not shown). The gate metal can be separated from the gate channel by the gate dielectric, such as SiO2, HfO2, or HfLaOX.

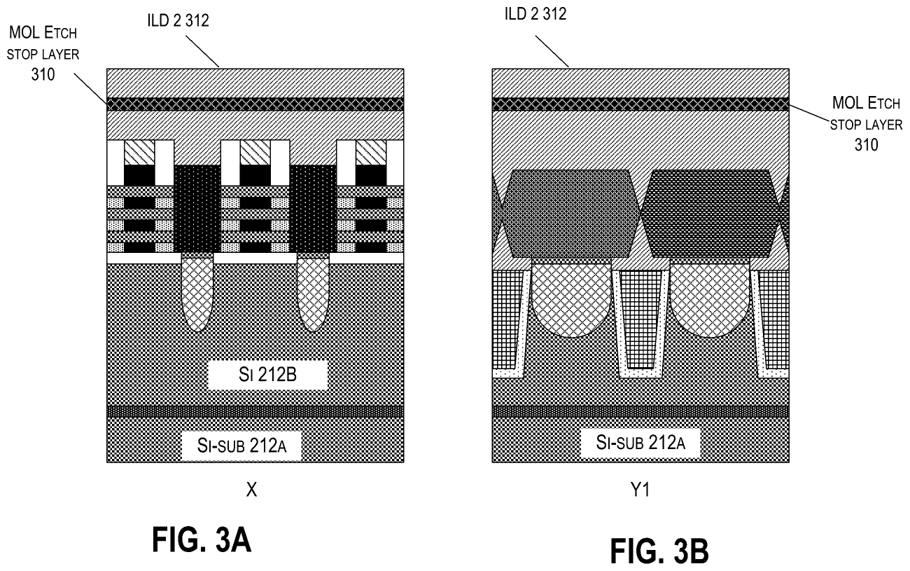

FIGS. 3A-3B illustrate side views of a semiconductor device after the formation of the etch stop layer, in accordance with some embodiments. In some embodiments, a MOL etch stop layer 310 is formed over the ILD1, followed by the formation of an additional layer of ILD, ILD2 312. In an embodiment, the MOL etch stop layer 310 is made of AlN. The ILD2 312 can be deposited onto the substrate using various techniques such as CVD, PECVD, or ALD. In some embodiments, after deposition, planarization techniques are employed to ensure a flat and smooth surface. In an embodiment, CMP can be used to remove excess material and achieve a uniform surface topography. In some embodiments, silicon dioxide (SiO2), or a low-k dielectric, e.g., organosilicates, fluorinated silicates, or porous materials, can be used as ILD2 312. Alternatively, polymer-based materials, such as polyimide or polybenzoxazole (PBO), can be used as ILD2 312. While in some embodiments, the ILD1 and ILD2 are made of different materials, in some embodiments, the ILD1 and ILD2 are made of the same materials.

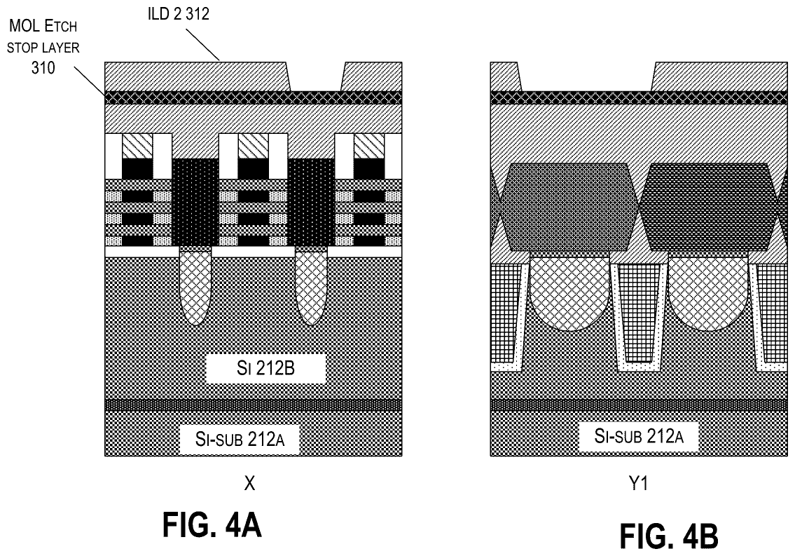

FIGS. 4A-4B illustrate side views of a semiconductor device after the patterning of the lateral contact, in accordance with some embodiments. In some embodiments, the lateral contact is patterned by removing portions of the ILD2 and exposing the surface of the MOL etch stop layer. That is, the removal of the ILD2 stops at the MOL etch stop layer.

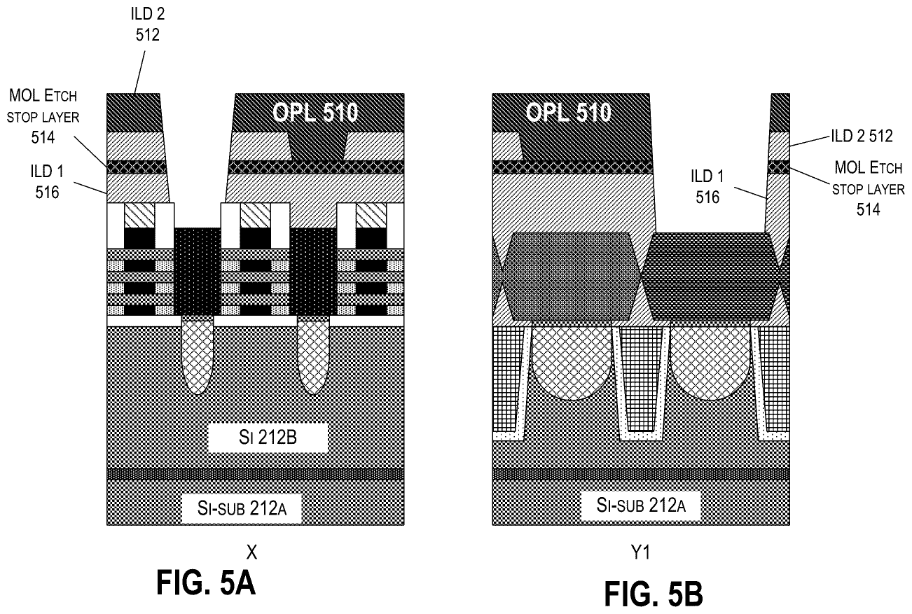

FIGS. 5A-5B illustrate side views of a semiconductor device after the patterning of the middle of line (MOL), in accordance with some embodiments. In some embodiments, an optical planarization layer, OPL, 510 is formed over the semiconductor device, followed by patterning the MOL by removing portions of the OPL 510, the ILD2 512, the MOL etch stop layer 514, and the ILD1 516, such that the surface of the source/drain region is exposed.

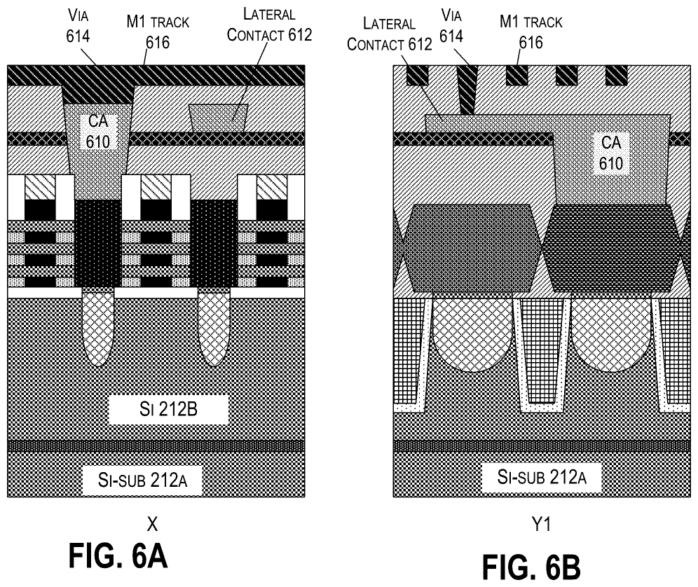

FIGS. 6A-6B illustrate side views of a semiconductor device after the MOL metallization, in accordance with some embodiments. In some embodiments, the OPL is removed, and the contact pattern and the lateral contact pattern are filled, i.e., metalized, by suitable metals to form the contact, CA, 610 and the lateral contact 612. While in some embodiments, the lateral contact 612 and the contact 610 are made of the same material, in some embodiments, the lateral contact 612 and the contact 610 are made of different materials. In an embodiment, the via 614 is formed above the contact 610 followed by forming the M1 track 616. Additional ILD can be deposited between the wires of the M1 track 616. Optionally, a CMP process can be performed.

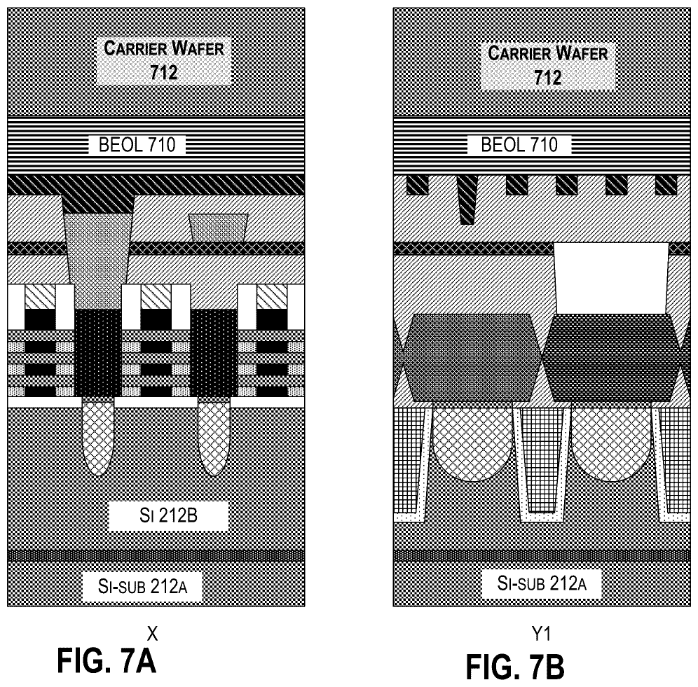

FIGS. 7A-7B illustrate side views of a semiconductor device after the formation of the back end of line (BEOL) 710, in accordance with some embodiments. In some embodiments, carrier wafer 712 bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

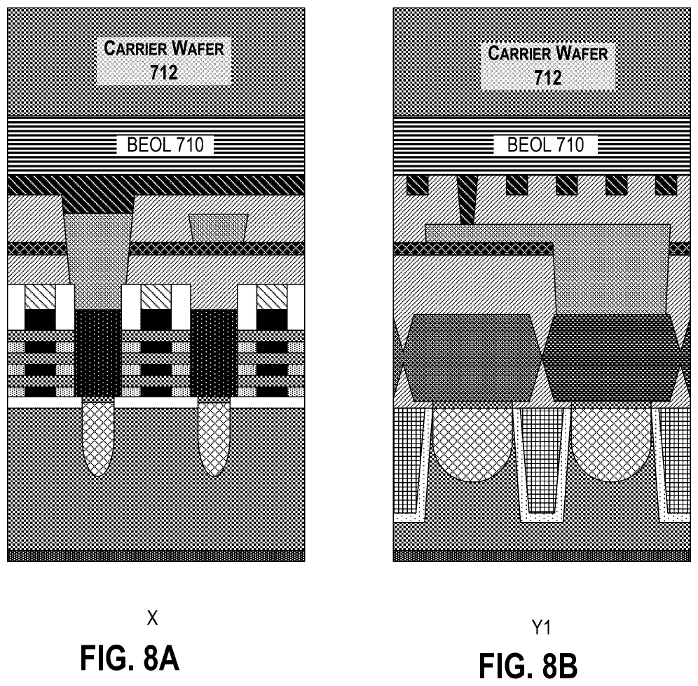

FIGS. 8A-8B illustrate side views of a semiconductor device after the substrate removal, in accordance with some embodiments. In some embodiments, the wafer is flipped, and the Si-sub is removed. The Si-sub removal process can proceed until reaching the etch stop layer. It should be noted that, for the sake of simplicity, the semiconductor device is not shown are flipped.

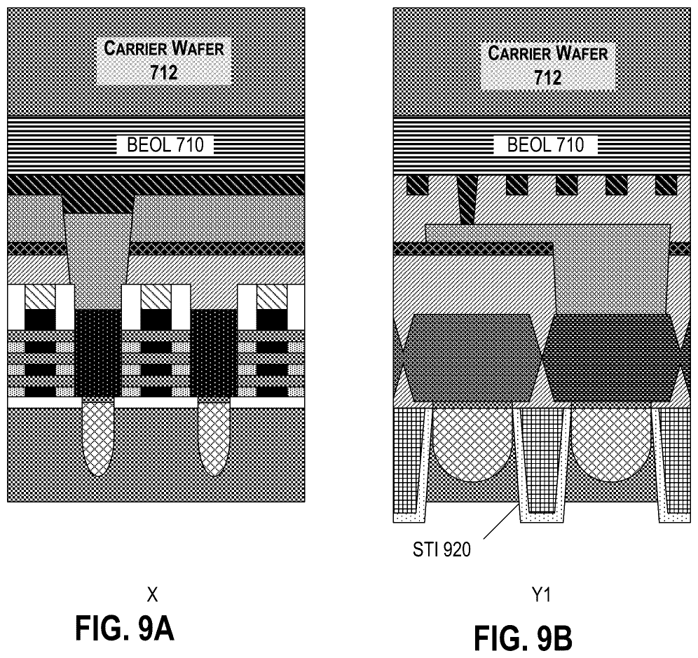

FIGS. 9A-9B illustrate side views of a semiconductor device after removal of the etch stop layer, in accordance with some embodiments. In an embodiment, the etch stop layer is removed, followed by the removal of the remaining Si-sub to form recessed portions above the bottom of the STI 920.

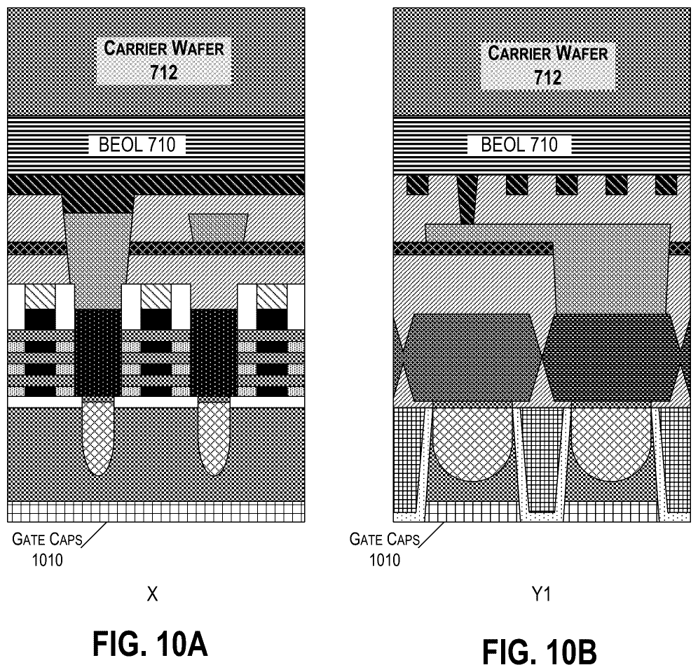

FIGS. 10A-10B illustrate side views of a semiconductor device after the formation of gate caps, in accordance with some embodiments. In some embodiments, gate caps 1010 are formed below the semiconductor device. The gate caps 1010 can be made of SiC or any other suitable material. Afterward, CMP can be performed, which stops on the STI liner.

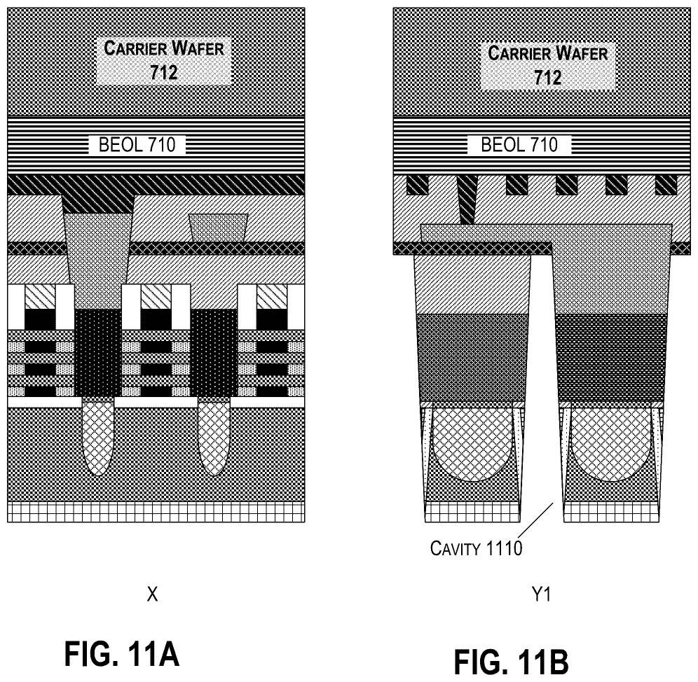

FIGS. 11A-11B illustrate side views of a semiconductor device after patterning the backside source/drain region-gate cut dielectric layers, in accordance with some embodiments. In some embodiments, the self-aligned backside source/drain region-gate cut dielectric layers are patterned by removing STI oxide and form a cavity 1110. The STI oxide can be removed by etching or any other suitable method.

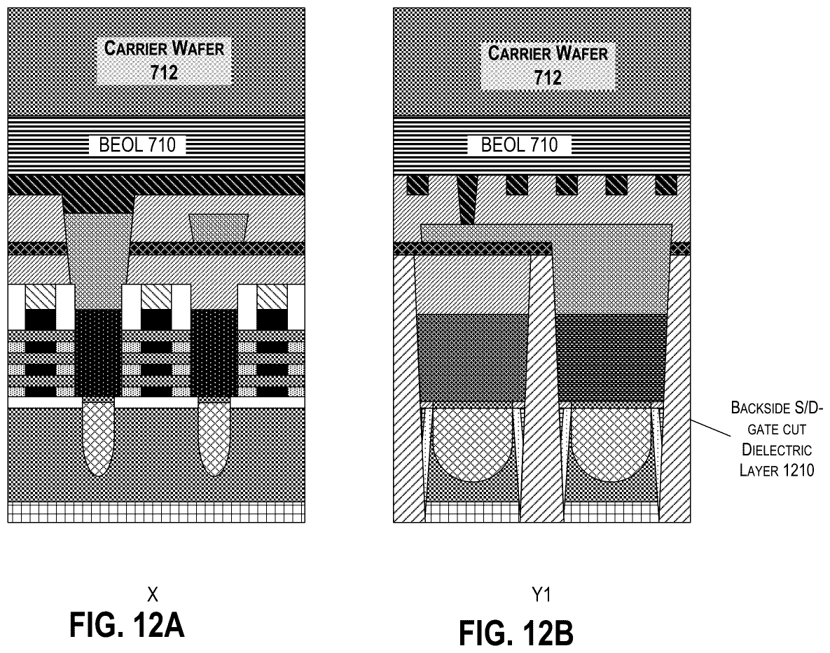

FIGS. 12A-12B illustrate side views of a semiconductor device after the formation of the backside source/drain region-gate cut dielectric layers, in accordance with some embodiments. In some embodiments, the removed portions of the STI oxide are filled to form the backside source/drain region-gate cut dielectric layers 1210.

The backside source/drain region-gate cut dielectric layers 1210 create a non-continuous gate across the semiconductor device, segmenting it into individual transistors. In some embodiments, the backside source/drain region-gate cut dielectric layers 1210 can physically disconnect the continuous gate regions and enable independent control over each of the transistors within the semiconductor device. The backside source/drain region-gate cut dielectric layers 1210 can help in reducing crosstalk between individual transistors, enhancing the overall semiconductor device performance. Further, by isolating each transistor, the backside source/drain region-gate cut dielectric layers 1210 can prevent the failure of one transistor from affecting the others, thereby improving the overall reliability of the semiconductor device.

In an embodiment, the backside source/drain region-gate cut dielectric layers 1210 provides flexibility in the semiconductor device design by allowing for the individual transistors within the semiconductor device to be accessed and controlled independently, which can be advantageous in custom circuit design. In some embodiments, the use of backside source/drain region-gate cut dielectric layers 1210 can allow for fine-tuning of the semiconductor device's characteristics post-fabrication, as different gate voltages can be applied to different transistors in the semiconductor device.

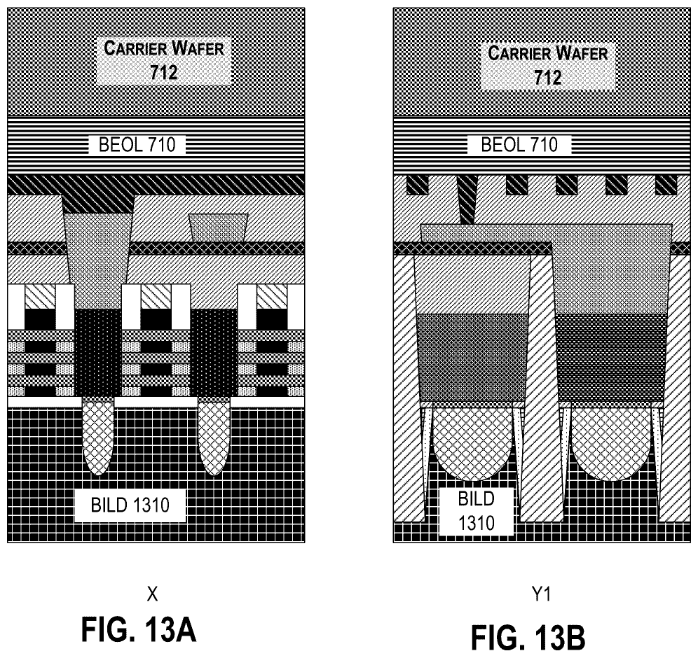

FIGS. 13A-13B illustrate side views of a semiconductor device after the planarization, in accordance with some embodiments. In some embodiments, the gate caps are removed selectively, followed by the removal of the remaining silicon substrate. A bottom ILD, BILD, 1310 layer is formed to cover the backside source/drain region-gate cut dielectric layers, the placeholders, the STI, and the BDI. In an embodiment, a CMP process is further processed after the formation of the BILD 1310. The BILD 1310 can be an insulating material or layer used to isolate and provide electrical insulation between the semiconductor device's active regions and the BSCA, and to prevent unwanted electrical contact between the active regions and the backside contact, ensuring the proper functioning and integrity of the semiconductor device. In various embodiments, the BILD 1310 can function as a protective layer, shielding the active regions of the semiconductor device from external contaminants, moisture, and mechanical stress. The BILD 1310 can further help prevent physical damage, such as scratches or particle contamination, which could adversely affect semiconductor device performance. Additionally, the BILD 1310 can function as a barrier against moisture ingress, which can cause corrosion and degradation of the semiconductor device's components. In some embodiments, the placeholder can be removed so that a recess is formed that exposes the bottom of the first source/drain region.

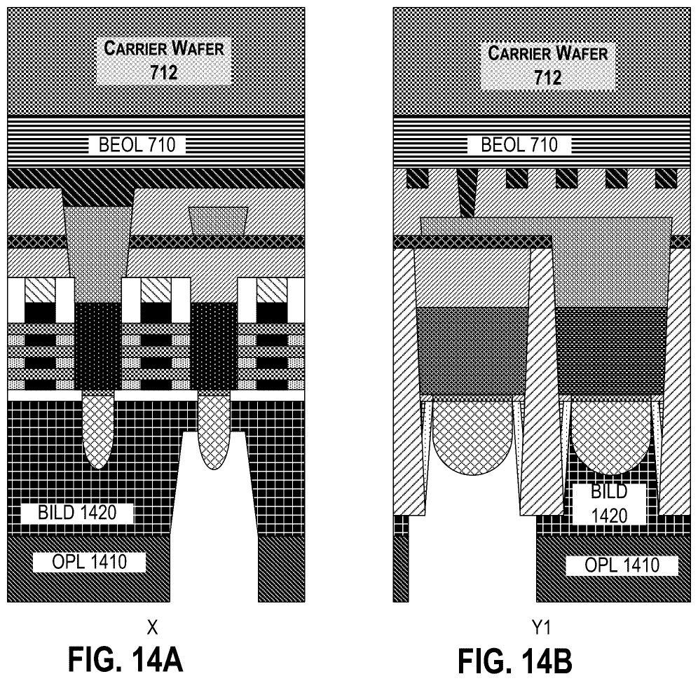

FIGS. 14A-14B illustrate side views of a semiconductor device after the backside contact (BSCA) patterning, in accordance with some embodiments. In some embodiments, the BSCA is patterned by selectively removing portions of the BILD, which can be performed by an etching process. To that end, an OPL 1410 can be formed over the BILD 1420 first and followed by the etching process. The etching process can stop at the STI liner and the backside source/drain region-gate cut dielectric layers.

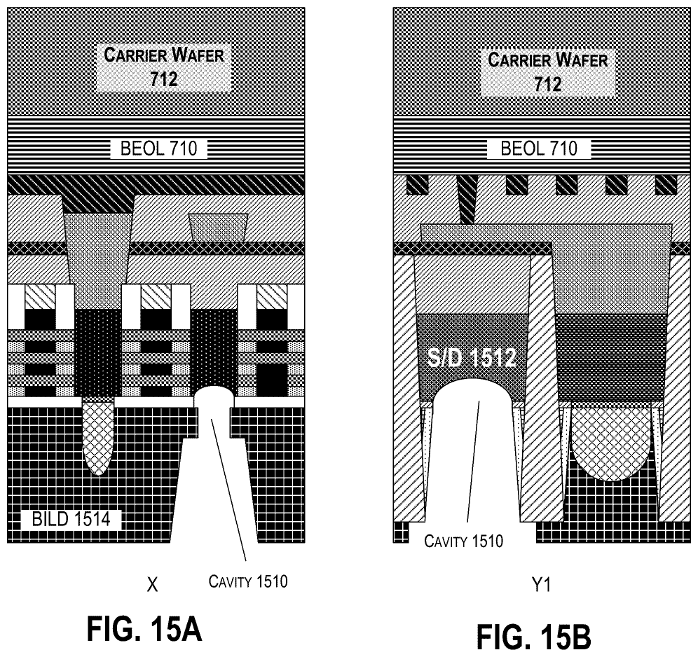

FIGS. 15A-15B illustrate side views of a semiconductor device after the removal of the placeholder, in accordance with some embodiments. In some embodiments, the placeholder, i.e., the sacrificial placeholder, is removed, and a cavity 1510 within the BILD is formed below the source/drain region 1512. The cavity 1510 can be formed by a reactive ion etching (RIE) technique. Generally, RIE is a dry etching process used in semiconductor device fabrication to remove materials from the surface of a substrate selectively. In some embodiments, RIE can involve using reactive ions and plasma to react with and remove specific materials chemically. In an embodiment, the RIE process begins by placing the semiconductor device inside a vacuum chamber. The chamber is then evacuated to create a low-pressure environment. Reactive gases, consisting of a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment. In some embodiments, Radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds, and remove silicon. In various embodiments, the RIE process can be selective, meaning it can mainly affect the target material, i.e., silicon, while leaving other materials, such as masking layers or underlying layers, relatively unaffected. In some embodiments, to achieve selective etching, an etch mask can be applied on the substrate surface prior to the RIE process. The etch mask protects certain regions from etching, allowing the reactive ions to remove the exposed material selectively.

The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is contaminant-free.

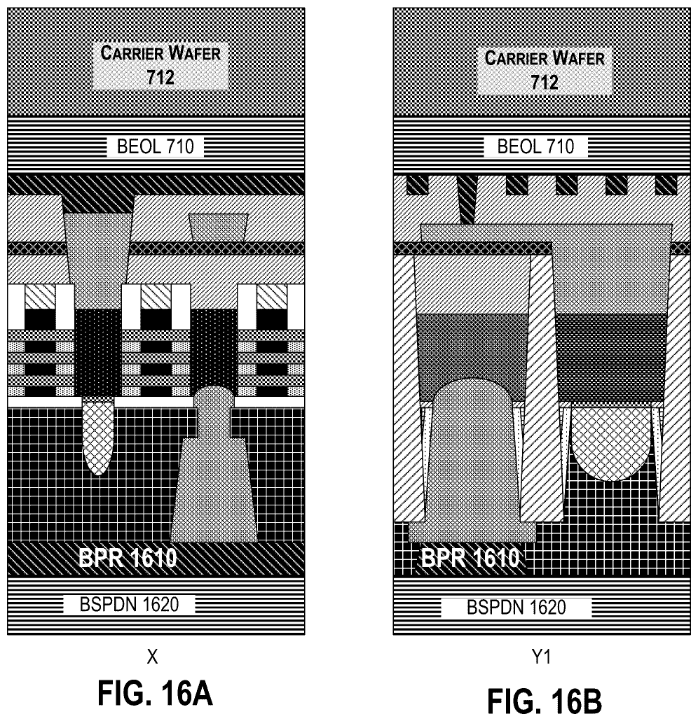

FIGS. 16A-16B illustrate side views of a semiconductor device after the backside contact metallization, in accordance with some embodiments. In some embodiments, a backside power rail, BPR, 1610 is formed to cover the BSCA and the BILD. The BPR 1610 can be covered by a backside power delivery network, BSPDN, 1620, which is used to connect the semiconductor device to other devices.

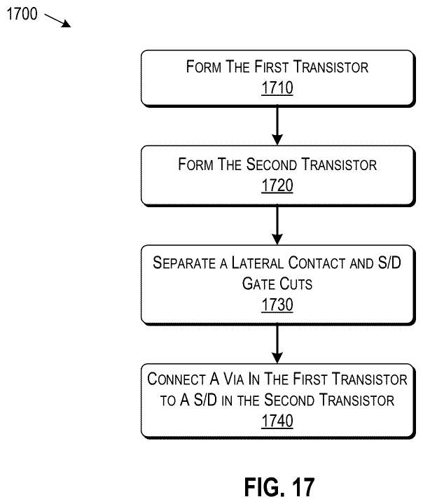

FIG. 17 illustrates a block diagram of a method 1700 for forming the semiconductor device, in accordance with some embodiments. As shown by block 1710, the first transistor is formed.

As shown by block 1720, the second transistor is formed adjacent to the first transistor.

As shown by block 1730, the lateral contact and a plurality of backside source/drain region-gate cut dielectric layers are separated through an etch stop layer within an ILD.

As shown by block 1740, the a via is connected over a first source/drain region of the first transistor to a second source/drain region of the second transistor through the lateral contact.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first transistor adjacent to a second transistor; and
an etch stop layer within an interlayer dialectic (ILD) configured to separate a lateral contact and a plurality of backside source/drain region-gate cut dielectric layers, wherein the lateral contact connects a via over a first source/drain region of the first transistor to a second source/drain region of the second transistor.

2. The semiconductor device of claim 1, wherein the lateral contact is located between the via and the etch stop layer.

3. The semiconductor device of claim 1, wherein a contact of the second source/drain region is extended through the etch stop layer.

4. The semiconductor device of claim 3, wherein the contact of the second source/drain region is located between two adjacent backside source/drain region-gate cut dielectric layers.

5. The semiconductor device of claim 1, wherein the first source/drain region is connected to a backside power rail (BPR) through a direct backside contact (BSCA).

6. The semiconductor device of claim 1, wherein the lateral contact is located above the first source/drain region and the second source/drain region.

7. A semiconductor device, comprising:
a first transistor adjacent to a second transistor; and
an etch stop layer within an interlayer dialectic (ILD) to separate a lateral contact and a plurality of backside source/drain region-gate cut dielectric layers, wherein a contact of a first source/drain region is extended through the etch stop layer.

8. The semiconductor device of claim 7, wherein the lateral contact connects a via over a second source/drain region of the first transistor to a second source/drain region of the second transistor.

9. The semiconductor device of claim 8, wherein the lateral contact is located between the via and the etch stop layer.

10. The semiconductor device of claim 7, wherein the contact of the first source/drain region is located between two adjacent backside source/drain region-gate cut dielectric layers.

11. The semiconductor device of claim 7, wherein a second source/drain region is connected to a backside power rail (BPR) through a direct backside contact (BSCA).

12. The semiconductor device of claim 7, wherein the lateral contact is located above the first source/drain region and a second source/drain region.

13. A method for forming a semiconductor device, the method comprising:
forming a first transistor;
forming a second transistor adjacent to the first transistor;
separating a lateral contact and a plurality of backside source/drain region-gate cut dielectric layers by an etch stop layer within an interlayer dialectic (ILD); and
connecting a via over a first source/drain region of the first transistor to a second source/drain region of the second transistor through the lateral contact.

14. The method of claim 13, further comprising extending a contact of the second source/drain region through the etch stop layer.

15. The method of claim 14, wherein the contact of the second source/drain region is located between two adjacent backside source/drain region-gate cut dielectric layers, and between the via and the etch stop layer.

16. The method of claim 13, further comprising connecting the first source/drain region to a backside power rail (BPR) through a direct backside contact (BSCA).

17. A method for forming a semiconductor device, the method comprising:
forming a first transistor;
forming a second transistor adjacent to the first transistor; and
extending a contact of the second source/drain region through an etch stop layer.

18. The method of claim 17, further comprising connecting a first source/drain region to a backside power rail (BPR) through a direct backside contact (BSCA).

19. The method of claim 17, wherein the contact of the second source/drain region is located between two adjacent backside source/drain region-gate cut dielectric layers, and between the via and the etch stop layer.

20. A semiconductor device, comprising:
a first transistor adjacent to a second transistor; and
an etch stop layer within an interlayer dialectic (ILD); and
a contact extending through the etch stop layer to connect a source/drain region to a back end of line (BEOL).

21. The semiconductor device of claim 20, wherein the ILD is configured to separate a lateral contact and a plurality of backside source/drain region-gate cut dielectric layers, wherein the lateral contact connects a via over a first source/drain region of the first transistor to a second source/drain region of the second transistor.

22. The semiconductor device of claim 21, wherein the lateral contact is located between the via and the etch stop layer.

23. The semiconductor device of claim 21, wherein the lateral contact is located above the first source/drain region and the second source/drain region.

24. The semiconductor device of claim 20, wherein a contact of a source/drain region is extended through the etch stop layer.

25. The semiconductor device of claim 20, further comprising a source/drain region connected to a backside power rail (BPR) through a direct backside contact (BSCA).
